(19) United States
(12) Patent Application Publication
(10) Pub. No.: US 2008/0079504 A1
(43) Pub. Date: Apr. 3, 2008

(54) QUADRATURE VOLTAGE CONTROLLED OSCILLATOR

(76) Inventors: Sang Jin BYUN, Daejeon (KR); Cheon Soo KIM, Daejeon (KR)

Correspondence Address: LADAS & PARRY LLP, 224 SOUTH MICHIGAN AVENUE, SUITE 1600, CHICAGO, IL, 60604, US

(21) Appl. No.: 11/778,133

(22) Filed: Jul. 16, 2007

(30) Foreign Application Priority Data
Sep. 29, 2006 (KR) 10-2006-0096302

(51) Int. Cl. H03B 27/00; H03B 5/12

(52) U.S. Cl. 331/45

(57) ABSTRACT

Provided is a quadrature voltage controlled oscillator having only one resonant mode characteristic. The quadrature voltage controlled oscillator has a structure in which two clocks generated from respective LC resonant circuits are 90 degrees out of phase with each other using a phase detector and a loop filter, instead of a general structure in which two LC tank resonant circuits are mutually coupled to constitute an LC quadrature voltage controlled oscillator. The quadrature voltage controlled oscillator includes two resonant circuits having the same oscillation frequency; and a phase controller receiving oscillation clocks of the two resonant circuits to control at least one of oscillation phases of the two resonant circuits according to a phase difference between the two oscillation clocks.

### CROSS-REFERENCE TO RELATED APPLICATION

This application claims priority to and the benefit of Korean Patent Application No. 2006-0096302, filed Sep. 29, 2006, the disclosure of which is incorporated herein by reference in its entirety.

### BACKGROUND

1. Field of the Invention

The present invention relates to a quadrature voltage controlled oscillator having only one resonant mode characteristic, and more particularly, to a quadrature voltage controlled oscillator having, instead of a general structure in which two resonant circuits are mutually coupled, a structure in which a phase detector and a loop filter are used to make two clocks generated from respective resonant circuits 90 degrees out of phase with each other.

2. Discussion of Related Art

A conventional quadrature voltage controlled oscillator includes two LC tank resonant circuits 110 and 120 which are cross-coupled to each other as illustrated in FIG. 1. With this structure, a resonant frequency of the quadrature voltage controlled oscillator is slightly different from resonant frequencies of the two LC tank resonant circuits, slightly shifted in proportion to the coupling strength between the circuits. Also, as illustrated in FIG. 1 clock signals CLK0, CLK90, CLK180 and CLK 270 of respective nodes are 90 degrees out of phase with each other.

FIG. 2 is a schematic block diagram illustrating linear analysis of the conventional quadrature voltage controlled oscillator having the two LC tank resonant circuits. When a phase difference between the two LC tank resonant circuits is represented as θ as illustrated in FIG. 2, a sum of phases within a loop is equal to 2θ+π. As a result, θ can be represented by Equations 1 to 3.

2θ+π=2nπ, n is an integer [Equation 1]

θ=nπ−π/2, n is an integer [Equation 2]

θ=+π/2(+90°) or −π/2(−90°) [Equation 3]

Therefore, a quadrature voltage controlled oscillator including two LC tank resonant circuits generally has two operating modes, and a phase difference between generated clocks may be selected as +90° or −90°. By actually manufacturing and testing a prototype chip, it has been confirmed that the quadrature voltage controlled oscillator has two operating modes and one of them is determined at random.

However, the conventional quadrature voltage controlled oscillator is generally implemented without startup circuits. Therefore, stable operation cannot be ensured when the oscillator is used in clock circuits, data recovery circuits, image-rejection receiver circuits, etc., in which the phase difference between its clocks must be exactly either +90° or −90°.

Another conventional quadrature voltage controlled oscillator has a structure in which two same-phase shifters are respectively added to to LC tank resonant circuits to select one of two operating modes. With this configuration, a phase error generated from the added phase shifter is added to the phase difference between clocks generated by the LC quadrature voltage controlled oscillator, making it difficult to maintain the phase difference between the clocks at exactly 90 degrees. Therefore, when the oscillator is used in clock circuits, data recovery circuits, image-rejection receiver circuits, etc., in which the phase difference between it's clocks must be exactly either +90° or −90°, all accurate phase difference between the clocks cannot be ensured.

### SUMMARY OF THE INVENTION

The present invention is directed to a quadrature voltage controlled oscillator capable of stably maintaining a phase difference between two oscillation clocks at 90 degrees using a simpler method.

For this purpose, when a quadrature voltage controlled oscillator is implemented using two resonant circuits, the present invention provides an LC quadrature voltage controlled oscillator having only one resonant mode characteristic, in which a separate phase controller is used to make two clocks generated from the respective resonant circuits 90 degrees out of phase with each other, instead of a general method in which the two resonant circuits are mutually coupled to constitute the quadrature voltage controlled oscillator.

The present invention is also directed to a quadrature voltage controlled oscillator that stably maintains a phase difference between two oscillation clocks at 90 degrees, and is easily integrated.

One aspect of the present invention provides a quadrature voltage controlled oscillator including: two resonant circuits having the same oscillation frequency; and a phase controller receiving oscillation clocks of the to resonant circuits to control at least one of the oscillation phases of the two resonant circuits according to a phase difference between the two oscillation clocks.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1A is a block diagram of a conventional LC quadrature voltage controlled oscillator;

FIG. 1B is a circuit diagram of an example of a resonant circuit of FIG. 1A;

FIG. 2 is a schematic block diagram illustrating linear analysis of the conventional LC quadrature voltage controlled oscillator;

FIG. 3A is a block diagram of an LC quadrature voltage controlled oscillator having a phase detector and a loop filter according to an exemplary embodiment of the present invention;

FIG. 3B is a circuit diagram of an example of a resonant circuit of FIG. 3A;

FIG. 4 is a circuit diagram of an example of the phase detector of FIG. 3A; and

FIGS. 5 to 7 illustrate waveforms of input and output portions of the phase detector of FIG. 4.

### DETAILED DESCRIPTION OF EXEMPLARY EMBODIMENTS

Hereinafter, exemplary embodiments of the present invention will be described in detail. However, the present invention is not limited to the embodiments disclosed below, but can be implemented in various forms. Therefore, the following embodiments are described in order for this disclosure to be complete and enabling to those of ordinary skill in the art.

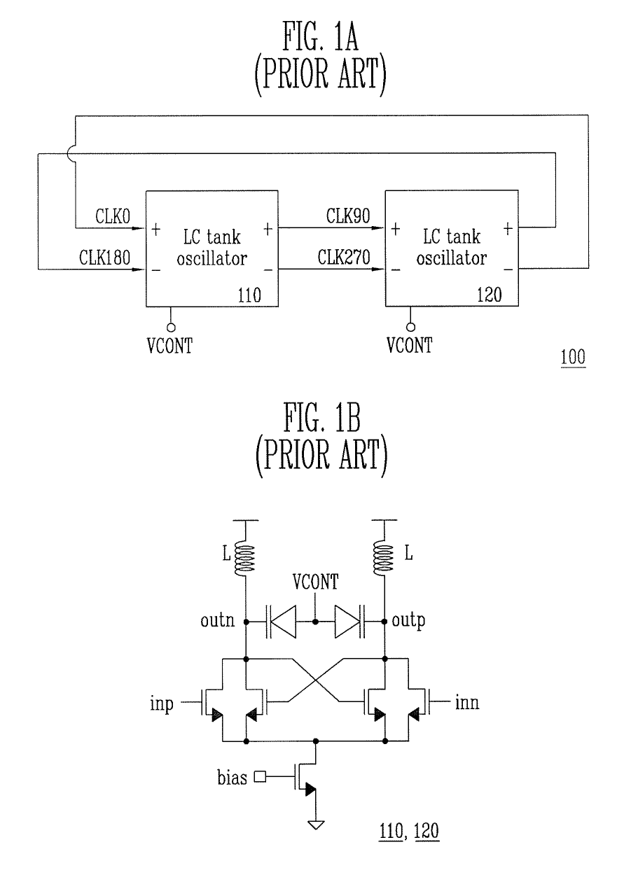

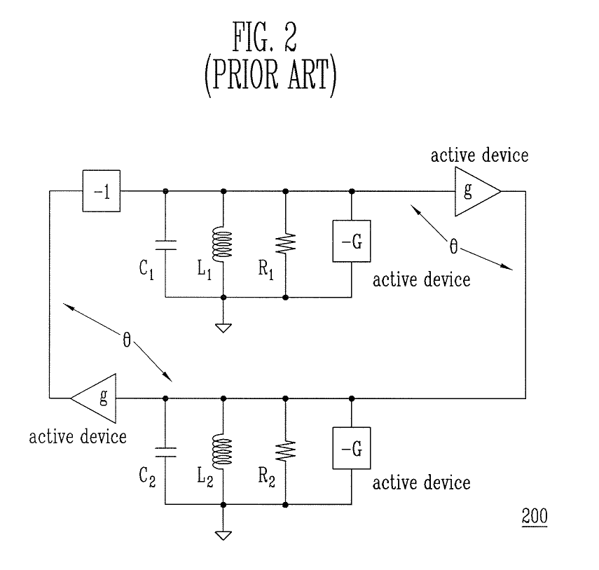

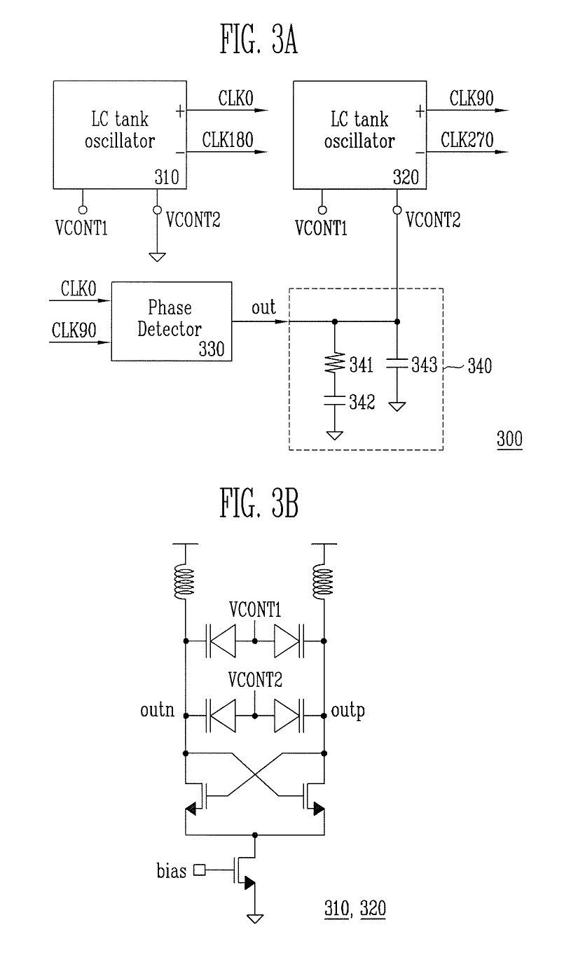

FIG. 3A is a circuit diagram of an LC quadrature voltage controlled oscillator according to the present invention. As illustrated in FIG. 3A, the LC quadrature voltage controlled oscillator includes two LC tank resonant circuits 310 and 320, a phase detector 330, and a loop filter 340 The two LC tank resonant circuits 310 and 320 are not cross-coupled to each other as illustrated in FIG. 1, but constitute a closed-loop by the phase detector 330 and the loop filter 340. Also, the two LC tank resonant circuits 310 and 320 generate clocks that are 90 degrees out of phase with each other by the phase detector 330 and the loop filter 340.

Clock signals generated at outputs of the LC tank resonant circuits may be represented as CLK0, CLK90, CLK180 and CLK270 according to phases. The phase detector 330 receives all of the clock signals CLK0, CLK90, CLK180 and CLK270 or receives only two signals CLK0 and CLK90 to detect a phase difference between the clocks.

The phase detector 330 outputs a current in proportion to the detected phase difference to the loop filter 340. In other words, when clocks are 90 degrees out of phase with each other, an average value of the output current is 0. Further, when the phase difference between the clocks is not 90 degrees the phase difference corresponding to the deviation from 90 degrees is converted to current to be output to the loop filter 340.

The loop filter 340 receives the output current of the phase detector 330 to convert the current to a voltage. Therefore, a phase controller including the phase detector 330 and the loop filter 340 outputs 0V when two input oscillation clocks are exactly 90 degrees out of phase. Further, when the phase difference is less than 90 degrees, the phase controller outputs a positive (or negative) voltage in proportion to the deviation from 90 degrees. Also, when the phase difference is greater than 90 degrees, the phase controller outputs a negative (or positive) voltage in proportion to the deviation from 90 degrees.

The voltage converted by the loop filter 340 acts as a phase control voltage VCONT2 with respect to the LC resonant circuit 320 of the LC quadrature voltage controlled oscillator. The phase difference between the clocks generated from the respective LC resonant circuits is maintained at exactly 90 degrees by closed loop operation.

Basically, each of the LC tank resonant circuits 310 and 320 illustrated in FIG. 3B includes a phase control varactor (a capacitor value is changed by VCONT2) that controls a phase and has less capacity, in addition to a frequency control varactor that controls frequency (a capacitor value is changed by VCONT1) that controls frequency. In other words, oscillation clock frequencies of the resonant circuits 310 and 320 are determined by the frequency control voltage VCONT1 that is input into a capacitance control voltage applying terminal of the frequency control varactor. Also, phases of the oscillation clocks are determined by the phase control voltage VCONT2 that is input into a capacitance control voltage applying terminal of the phase control varactor. Here, in the phase control varactor, the phase control voltage VCONT2 is a capacitance control voltage.

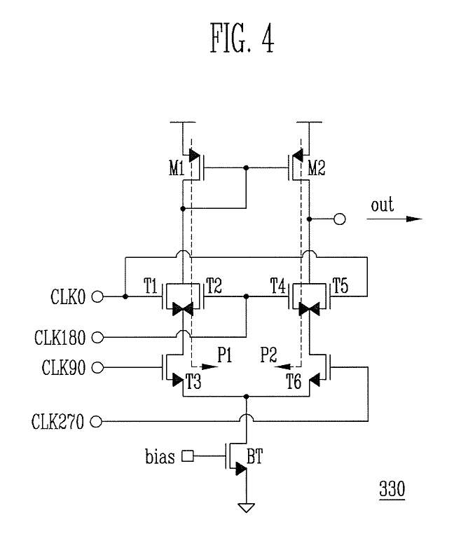

FIG. 4 illustrates one embodiment of the phase detector 330 that is implemented with a Gilbert cell type circuit. The phase detector may receive only CLK0 and CLK90 to be implemented as a single-ended input stage. Also, the phase detector may receive CLK0 and CLK180, and CLK90 and CLK270 to be implemented as a differential input stage. FIG. 4 illustrates a case when the phase detector is implemented as the differential input stage.

The phase detector 330 implemented as the differential input stage includes two symmetrical current paths P1 and P2 driven by current mirrors M1 and M2 and a bias transistor BT with the same amount of current. The current paths include first and second MOS transistors T1, T2, T4, and T5 that control the corresponding current paths and are connected in parallel with each other and third MOS transistors T3 and T6 that control the current paths and are connected in series with the first and second MOS transistors T1, T2, T4, and T5.

Here, as illustrated, an oscillation clock CLK0 of one of the resonant circuits is input to gates of the first MOS transistors T1 and T5 of the current paths. Further, an inverted clock CLK180 of the oscillation clock of one of the resonant circuits is input to gates of the second MOS transistors T2 and T4 of the current paths.

In addition, an oscillation clock CLK90 of the other of the resonant circuits is input to a gate of the third MOS transistor T3 of one current path P1, and an inverted clock CLK270 of the oscillation clock of the other of the resonant circuits is input to a gate of the third MOS transistor T6 of the other current path P2.

FIG. 5 illustrates waveforms of input and output portions of the phase detector 330 illustrated in FIG. 4. In FIG. 5, for better explanation and understanding, two inputs CLK0 and CLK90 of the phase detector 330 are exactly 90 degrees out of phase. In this case, it can be known that output current out is zero (0) in average.

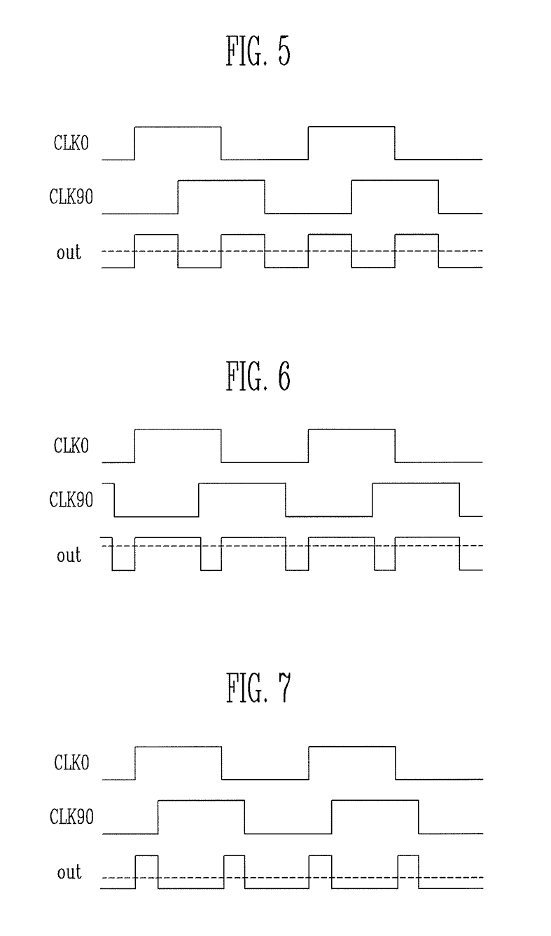

Meanwhile, as illustrated in FIG. 6, when the phase difference between the two inputs CLK0 and CLK90 of the phase detector 330 is greater than 90 degrees, the output current out is a positive value (+) in average. In contrast, as illustrated in FIG. 7, when the phase difference between the two inputs CLK0 and CLK90 of the phase detector 330 is less than 90 degrees, the output current out is a negative value (−) in average.

As described above, a quadrature voltage controlled oscillator of the present invention having the above structure detects a phase difference between two clocks using a phase detector and a loop filter, and controls phases of oscillation clocks of resonant circuits according to the detected phase difference so that the phase difference between the oscillation clocks generated from the LC quadrature voltage controlled oscillator is maintained at exactly 90 degrees.

Also, the quadrature voltage controlled oscillator of the present invention is easily integrated while maintaining high performance.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A quadrature voltage controlled oscillator comprising:
two resonant circuits having the same oscillation frequency; and
a phase controller receiving oscillation clocks of the two resonant circuits to control at least one of oscillation phases of the two resonant circuits according to a phase difference between the two oscillation clocks.

2. The quadrature voltage controlled oscillator of claim 1, wherein the phase controller outputs:
a voltage of 0 when the two input oscillation clocks are 90 degrees out of phase;
a positive (or negative) voltage in proportion to a deviation from 90 degrees when the phase difference is less than 90 degrees; and
a negative (or positive) voltage in proportion to a deviation from 90 degrees when the phase difference is greater than 90 degrees.

3. The quadrature voltage controlled oscillator of claim 1, wherein at least one of the two resonant circuits comprises a varactor for controlling a phase of the oscillation clock, and the phase controller determines a capacitance control voltage with respect to the varactor.

4. The quadrature voltage controlled oscillator of claim 3, wherein the two resonant circuits respectively comprise varactors for controlling the phases of the oscillation clocks, a capacitance control voltage applying terminal of the varactor of one resonant circuit is connected to a ground voltage terminal, and a capacitance control voltage applying terminal of the varactor of the other resonant circuit is connected to an output terminal of the phase controller.

5. The quadrature voltage controlled oscillator of claim 1, wherein the phase controller comprises:
a phase detector for generating a current corresponding to the phase difference between the two oscillation clocks; and
a loop filter for converting an output current of the phase detector to a voltage.

6. The quadrature voltage controlled oscillator of claim 5, wherein the phase detector comprises:
two symmetrical current paths;
first and second MOS transistors connected in parallel with each other to control the current paths; and
a third MOS transistor connected in series with the first and second MOS transistors to control the current paths,
wherein an oscillation clock of one resonant circuit is input to gates of the first MOS transistors of the current paths; an inverted clock of the oscillation clock of the one resonant circuit is input to gates of the second MOS transistors of the current paths; an oscillation clock of the other resonant circuit is input to a gate of the third MOS transistor of one current path; and an inverted clock of the oscillation clock of the other resonant circuit is input to a gate of the third MOS transistor of the other current path.

7. The quadrature voltage controlled oscillator of claim 1, wherein the two resonant circuits are LC tank resonant circuits.
